(19) United States
(12) Patent Application Publication
(10) Pub. No.: US 2013/0058058 A1
(43) Pub. Date: Mar. 7, 2013

(54) USB PLUG AND USB MODEM

(71) Applicants: Sang Don PARK, Seoul (KR); Jin Pyo KIM, Seoul (KR)

(72) Inventors: Sang Don PARK, Seoul (KR); Jin Pyo KIM, Seoul (KR)

(73) Assignee: PANTECH CO., LTD., Seoul (KR)

(21) Appl. No.: 13/464,293

(22) Filed: May 4, 2012

(30) Foreign Application Priority Data
Sep. 2, 2011 (KR) 10-2011-0089224

(51) Int. Cl. H05K 7/00; H05K 13/00

(52) U.S. Cl. 361/752; 361/748; 29/601

(57) ABSTRACT

A USB plug includes: a USB terminal; a PCB connected to one end of the USB terminal; a cable connected to the PCB; a hinge coupling member including first and second through-holes allowing the cable to pass through; and a connection terminal disposed at the end of the cable extending through the first and second through-holes of the hinge coupling member. The USB plug provides an electrical connection between the PCB of the USB modem and the PCB of the USB plug to ground the antenna.

### CROSS-REFERENCE TO RELATED APPLICATION

This application claims priority from and the benefit of Korean Patent Application No. 10-2011-0089224, filed on Sep. 2, 2011, which is hereby incorporated by reference for all purposes as if fully set forth herein.

### BACKGROUND

1. Field

Exemplary embodiments of the present invention relate to a USB plug and a USB modem, and more particularly, to a USB plug with a structure that may improve an antenna performance of a USB modem and decrease the size of the USB plug, and a USB modem using the same.

2. Discussion of the Background

Wireless USB modems have recently been used for data communication in mobile communication networks. The trend is to decrease USB modems size.

According to the related art, the ground length of a wireless USB modem is at least 12 cm in order to meet the total radiated power (TRP) performance of an LTE MIMO antenna used in the 700 MHz frequency band. That is, an antenna used for a USB modem has a minimum Printed Circuit Board (“PCB”) ground length. This is because the length of the ground body is at least 12 cm, which is λ/4, when the 700 MHz frequency band is used in the LTE band. TRP refers to a sum of all powers actually radiated from an antenna irrespective of direction or polarity and is a value indicating the transmission performance of a terminal apparatus. Further, a ground is configured to have a minimum area in a radio frequency (“RF”) band in order to satisfactorily function as a ground.

For this reason, the USB modem according to the related art has a restriction in that as PCB length increases, the entire size of the USB modem increases. If the ground length is reduced the TRP characteristics of an antenna may deteriorate at the 700 MHz frequency band of the LTE band.

FIG. 1 is a diagram illustrating a USB plug of a USB modem according to the related art.

Referring to FIG. 1, a USB plug 10 includes a four-pin connector 20, a cable 30, and a USB terminal 40.

The four-pin connector 20 is connected to a PCB (not shown) of the USB modem. The USB terminal 40 can be connected to an external electronic apparatus, which may perform data communication. The external electronic apparatus is electrically connected to the PCB of the USB modem via the cable 30 and the four-pin connector 20.

The cable 30 according to the related art includes wires 32 serving as conductors and an insulation tape coating the wires 32. The insulation tape is removed at the end of the cable 30, so that the wires 32 are exposed. The exposed wires 32 are connected to USB plug terminals 42 which are parts of the USB terminal 40.

The effect of noise producing components that influence a USB modem should be reduced to meet antenna performance standards, such as, total isotropic sensitivity (TIS) at a low band frequency (i.e., equal to or less than 1 GHz). TIS refers to an average power that is obtainable from an ideal isotropic antenna and is a value indicating the reception performance of a terminal apparatus. The cable 30, which includes the wires 32 and the insulation, has a disadvantage in that its noise-blocking effect may not be sufficient for use with USB modems.

The above information disclosed in this Background section is only for enhancement of understanding of the background of the invention and therefore it may contain information that does not form any part of the prior art.

### SUMMARY

Exemplary embodiments of the present invention provide a USB plug, and in particular, a USB plug for a USB modem.

Exemplary embodiments of the present invention also provide a USB modem, and in particular, a USB modem with an additional ground in a USB plug portion of the modem.

Additional features of the invention will be set forth in the description which follows, and in part will be apparent from the description, or may be learned by practice of the invention.

An exemplary embodiment of the present invention discloses a universal serial bus (USB) plug, including: a USB terminal; a printed circuit board (PCB) connected to the USB terminal; a micro-coaxial (MCX) cable connected to the PCB; a connection terminal connected to the MCX cable; a cushion arranged in a coupling member, and a conductive member arranged in the coupling member and electrically connected to the cushion; wherein the MCX cable passes through the coupling member and a portion of the MCX cable is electrically connected to the cushion.

An exemplary embodiment of the present invention also discloses a universal serial bus (USB) modem, including: a first case housing an antenna; a second case housing a first printed circuit board (PCB); and a USB plug including: a USB terminal; and a second PCB connected to the USB terminal, wherein the antenna is grounded to the second PCB via a micro-coaxial (MCX) cable.

An exemplary embodiment of the present invention also discloses a method for forming a universal serial bus (USB) modem, including: arranging an antenna in a first case; arranging a first printed circuit board (PCB) in a second case; connecting a second PCB to a USB terminal; and connecting a first end of a micro-coaxial (MCX) cable to the second PCB, wherein the antenna is grounded to the second PCB via the MCX cable.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, is illustrate embodiments of the invention, and together with the description serve to explain the principles of the invention.

FIG. 1 is a diagram illustrating a USB plug of a USB modem according to the related art.

FIG. 2 is a perspective view illustrating a USB modem according to an exemplary embodiment of the present disclosure.

FIG. 3 is a perspective view illustrating a USB modem in an open position according to an exemplary embodiment of the present disclosure.

FIG. 4A is a diagram illustrating a case of a USB modem in FIG. 2 according to an exemplary embodiment of the present disclosure.

FIG. 4B is a diagram illustrating a case of a USB modem according to an exemplary embodiment of the present disclosure.

FIG. 5 is a plan view illustrating a USB plug according to an exemplary embodiment of the present disclosure.

FIG. 6 is an exploded perspective view illustrating the USB plug of FIG. 5.

FIG. 7 is a plan view illustrating the USB plug of FIG. 5 according to an exemplary embodiment of the present disclosure.

FIG. 8 is a cross-sectional view illustrating an MCX cable taken along the line A-A of FIG. 7.

FIG. 9 is a cross-sectional view illustrating a connection member according to an exemplary embodiment of the present disclosure.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements.

The terminology used herein is for the purpose of describing particular embodiments only and is not intended to be limiting of the present disclosure. As used herein, the singular forms “a,” “an,” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first,” “second,” and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. It will be understood that when an element is referred to as being “on” or “connected to” another element, it can be directly on or directly connected to the other element, or intervening elements may be present. In contrast, when an element is referred to as being “directly on” or “directly connected to” another element, is there are no intervening elements present.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, a USB plug and a USB modem according to exemplary embodiments of the disclosure will be described in more detail with reference to the accompanying drawings.

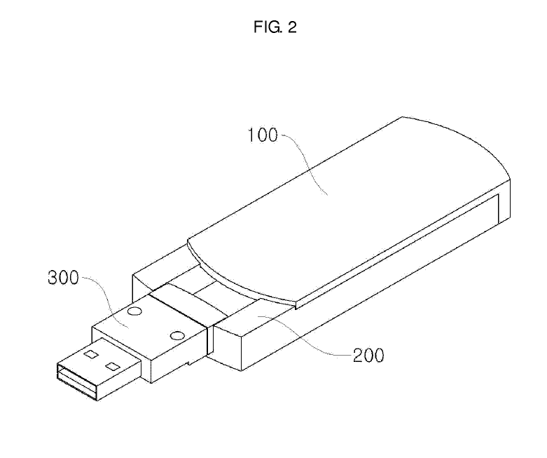

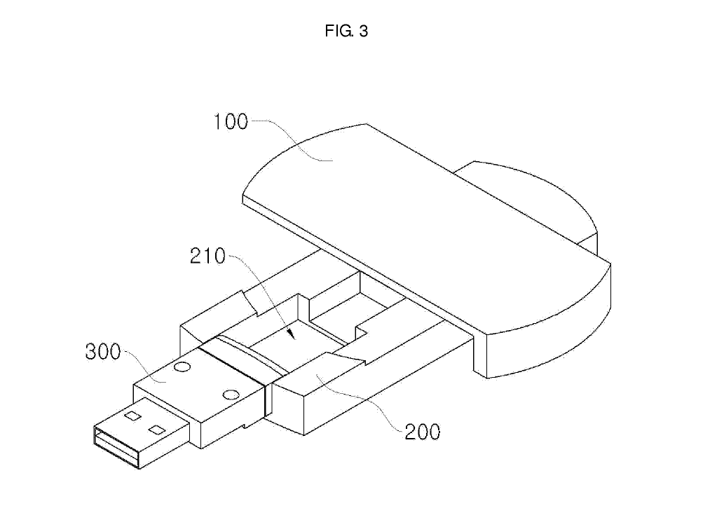

FIG. 2 is a perspective view illustrating a USB modem according to an exemplary embodiment of the disclosure. FIG. 3 is a perspective view illustrating a USB modem in an open position according to an exemplary embodiment of the present disclosure.

Referring to FIG. 2 and FIG. 3, the USB modem includes a first case 100 having an antenna included therein, a second case 200 in contact with the first case 100, and a USB plug 300 arranged on the end of the second case 200.

As shown in FIG. 3, the first case 100 is rotatable relative to the second case 200. When the first case 100 is rotated, an accommodation groove 210 on a surface of the second case 200 is exposed. The USB plug 300 may be rotated to be accommodated in the accommodation groove 210, which may provide compactness of the USB modem.

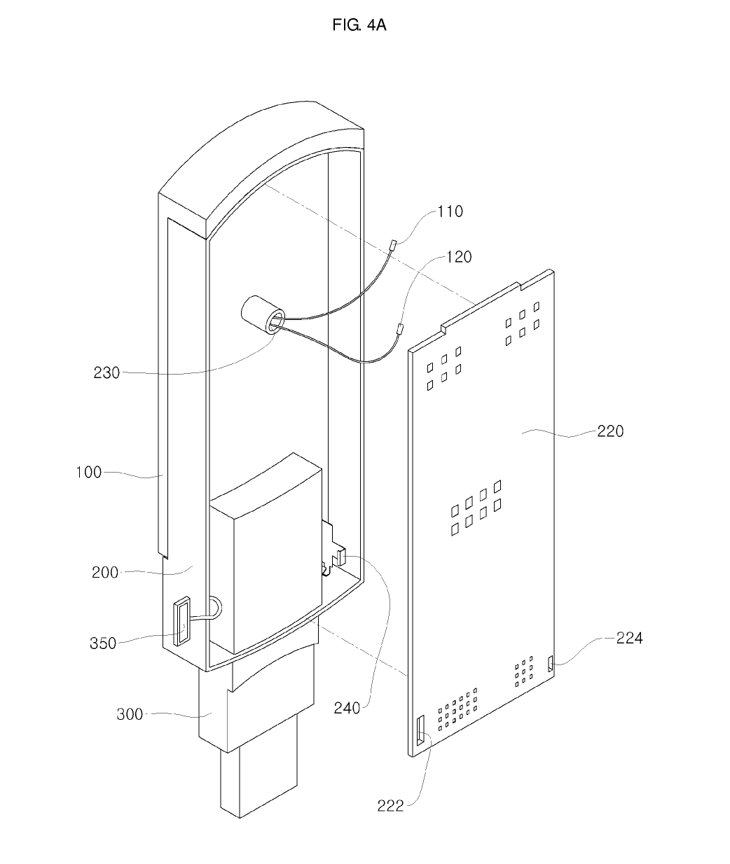

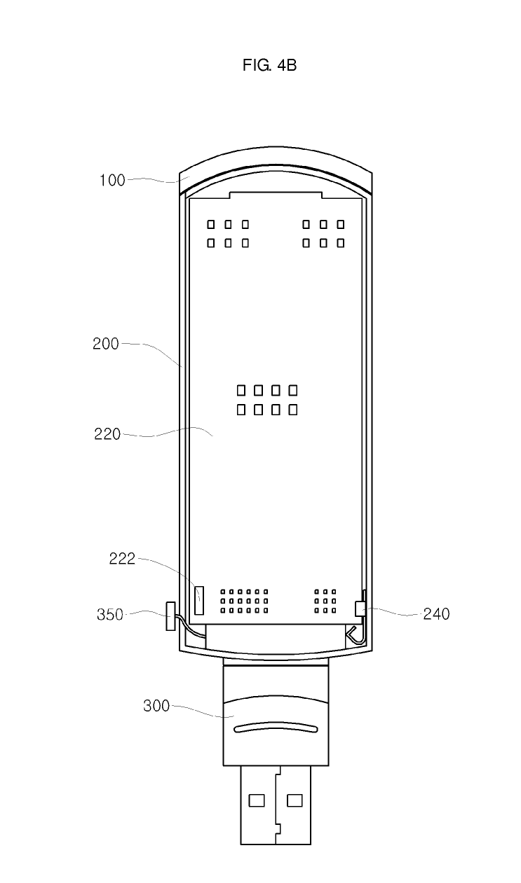

FIG. 4A is a diagram illustrating a case of a USB modem according to an exemplary embodiment of the present disclosure. FIG. 4B is a diagram illustrating a case of a USB modem according to an exemplary embodiment of the present disclosure. Referring to FIG. 4A and FIG. 4B, a main PCB 220 is disposed inside the second case 200. The antenna in is the first case 100 is connected to the main PCB 220 by antenna connection line 110 and antenna connection line 120 extending through a through-hole 230 of the second case 200. The main PCB 220 serves as a ground for the antenna.

A first connection port 222 to which the USB plug 300 is connected may be arranged at one end of the main PCB 220. When the USB plug 300 is connected to the first connection port 222, the ground for the antenna may extend up to both the main PCB 220 and the USB plug 300.

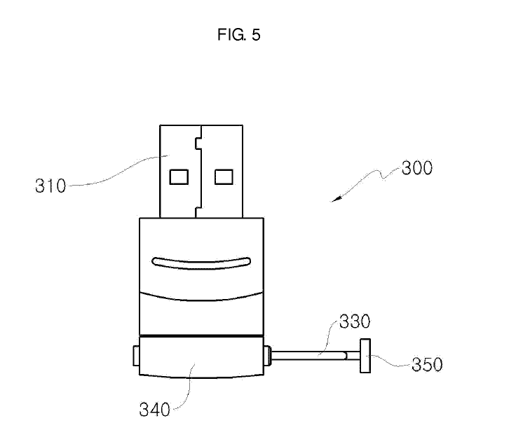

Further, a connection member 240 may be provided inside the second case 200. The connection member 240 may be connected to a second connection port 224 arranged in the main PCB 220. The connection member 240 electrically connects the main PCB 220 to one end of a hinge coupling member 340 (see FIG. 5) of the USB plug 300.

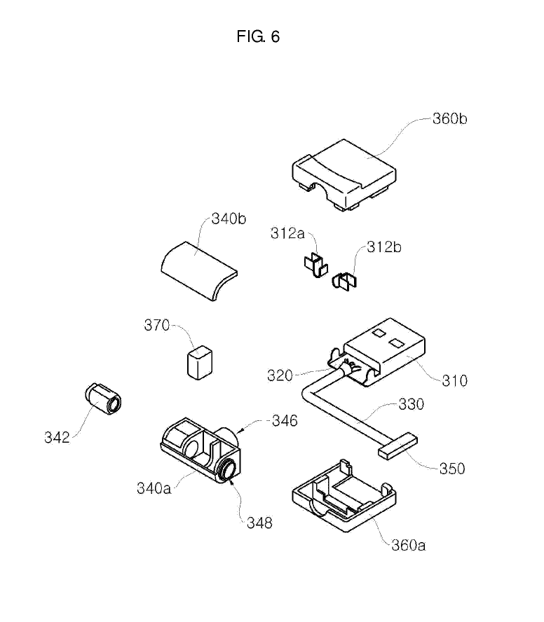

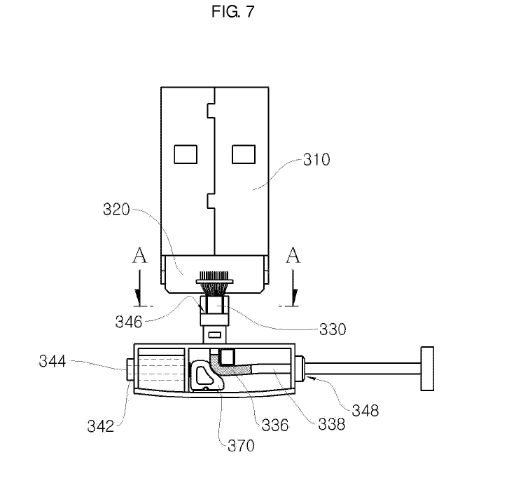

FIG. 5 is a plan view illustrating a USB plug according to an exemplary embodiment of the present disclosure. FIG. 6 is an exploded perspective view illustrating the USB plug of FIG. 5. FIG. 7 is a plan view illustrating the USB plug of FIG. 5 according to an exemplary embodiment of the present disclosure.

Referring to FIG. 5, FIG. 6, and FIG. 7, the USB plug 300 includes a USB terminal 310, a PCB 320 connected to one end of the USB terminal 310, a micro-coaxial (MCX) cable 330 connected to the PCB 320, a hinge coupling member 340 including a top 340b and a base 340a including a first through-hole 346 and a second through-hole 348 that allow the MCX cable 330 to pass through hinge coupling member 340, and a connection terminal 350 at one end of the MCX cable 330 extending through the first through-hole 346 and the second through-hole 348 of the hinge coupling member 340. The first through-hole 346 and the second through-hole 348 of the hinge coupling member 340 may be perpendicular to each other.

Referring again to FIG. 4A and FIG. 4B, although depicted as separate, the connection terminal 350 may be arranged to connect to first connection port 222.

Referring again to FIG. 5, FIG. 6, and FIG. 7, the hinge coupling member 340 of the USB plug 300 may have a hinge structure at one end or both ends and may be connected to the second case 200 by a hinge.

A hinge connection portion 342 is connected to one end of the hinge coupling member 340. A conductive member 344 is arranged in the hinge coupling portion 342. One end of a cushion 370 comes into contact with the conductive member 344. The other end of the cushion 370 comes into contact with the connection member 240 shown in FIG. 4 and is electrically connected to the main PCB 220. The cushion 370 has both electric conductivity and reference elasticity. The cushion 370 is arranged in the hinge coupling member 340 so that parts of the conductive member 344 and the MCX cable 330 are indirectly electrically connected with each other. Accordingly, the ground for the antenna of the USB modem may extend up to both the main PCB 220 and the PCB 320 inside the USB plug 300 since the connection terminal 350 is connected to the first connection port 222 to be connected to the main PCB 220, and is also connected the main PCB 220 through the connection member 240 provided inside the second case 200.

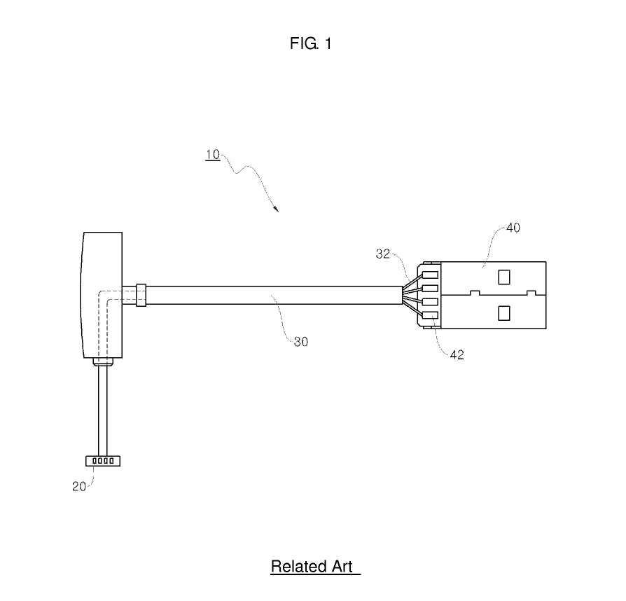

In comparison, USB plug 10 of FIG. 1 may not serve as a ground for an antenna because the cable 30 includes a four-pin connector 20 directly connected to a USB plug terminal 42 in the USB plug 10.

Referring back to FIG. 5, FIG. 6, and FIG. 7, the ground for the antenna may extend from the main PCB 220 up to the PCB 320 inside the USB plug 300 since the PCB 320 with a reference area is disposed between the USB terminal 310 and the MCX cable 330 in the USB plug 300. Accordingly, it is possible to provide total radiated power (TRP) performance of the antenna even at a low band frequency, such as, equal to or less than 1 GHz.

Furthermore, if the USB plug 300 is connected to an electronic apparatus such as a laptop computer, a ground of the electronic apparatus may be utilized as the ground for the antenna of the USB modem, thereby considerably improving the TRP performance of the antenna. The entire size of the USB modem may be reduced if the main PCB 220 used in the USB modem may be reduced in size.

Housing 360a and housing 360b of the USB plug 300 are connected to each other around first through-hole 346 of the hinge coupling member 340 and are rotatable up to a reference angle relative to the hinge coupling member 340 through rotation spring 312a and rotation spring 312b disposed therein.

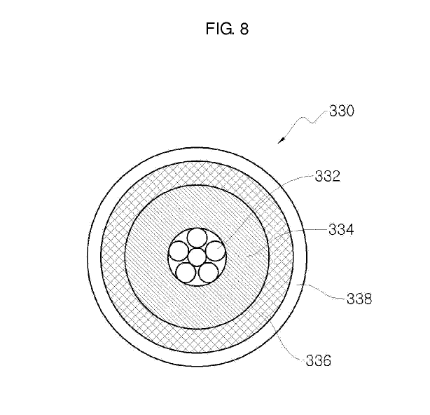

FIG. 8 is a cross-sectional view illustrating the MCX cable taken along the line A-A of FIG. 7.

Referring to FIG. 8, the MCX table 330 includes a conductor 332, an insulator 334, an EMI shielding tape 336, and a jacket tape 338 sequentially from the center of the MCX table 330.

A cable used in the related art generally includes a conductor and an insulator. In the MCX cable 330, the addition of the EMI shielding tape 336 and the jacket tape 338 may increases the blocking of external noise. Accordingly, by applying the MCX cable 330 to the USB plug 300 it may be possible to improve the total isotropic sensitivity (TIS) performance of the antenna.

Referring again to FIG. 7, the jacket tape 338, which is a non-conductive substance surrounding the EMI shielding tape 336, is removed at a partial region of the MCX is cable 330 in order to electrically connect the main PCB 220, the conductive member 344, the cushion 370, the MCX cable 330, and the PCB 320 to each other. Therefore, the EMI shielding tape 336 which is conductive may directly contact the cushion 370.

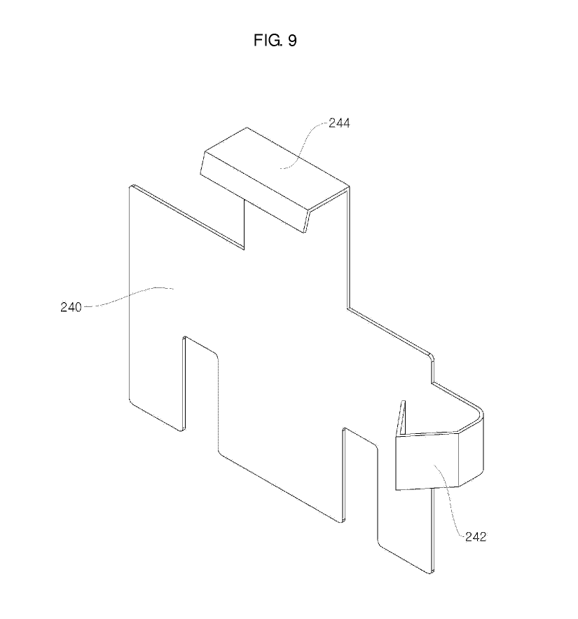

FIG. 9 is a perspective view illustrating the connection member according to an exemplary embodiment of the present disclosure.

Referring to FIG. 9, the connection member 240 electrically connects the main PCB 220 to one end of the hinge coupling member 340 of the USB plug 300. A first connection portion 242 of the connection member 240 is connected to the conductive member 344 of the hinge coupling member 340, and a second connection portion 244 is connected to the second connection port 224 of the main PCB 220 to assist with the electric connection from the main PCB 220 to the PCB 320.

The USB plug has a structure in which the ground area for the antenna of the USB modem expands. It is possible to improve the degree of design freedom while reducing the entire size of the USB modem.

Further, the USB plug includes the MCX cable to reduce noise from the outside. Accordingly, it may be possible to provide TIS performance of the antenna at a low band frequency (such as, equal to or less than 1 GHz).

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A universal serial bus (USB) plug, comprising:
a USB terminal;
a printed circuit board (PCB) connected to the USB terminal;
a micro-coaxial (MCX) cable connected to the PCB;
a connection terminal connected to the MCX cable;
a cushion arranged in a coupling member; and
a conductive member arranged in the coupling member and electrically connected to the cushion,
wherein the MCX cable passes through the coupling member and a portion of the MCX cable is electrically connected to the cushion.

2. The USB plug of claim 1, wherein a portion of an electromagnetic interference (EMI) shielding tape of the MCX cable is exposed to electrically connect the MCX cable to the cushion.

3. The USB plug of claim 1, wherein the MCX cable comprises:
a conductor;
an insulator surrounding the conductor;
an electromagnetic interference (EMI) shielding tape surrounding the insulator; and
a jacket tape surrounding the EMI shielding tape.

4. The USB plug of claim 4, wherein the coupling member comprises:
a first through-hole; and
a second through-hole perpendicular to the first through-hole,
wherein the MCX cable extends through the first through-hole and the second through-hole.

5. A universal serial bus (USB) modem, comprising:
a first case housing an antenna;
a second case housing a first printed circuit board (PCB); and
a USB plug comprising:
a USB terminal; and
a second PCB connected to the USB terminal,
wherein the antenna is grounded to the second PCB via a micro-coaxial (MCX) cable.

6. The USB modem of claim 5, wherein the USB plug further comprises:
a conductive member electrically connected to the MCX cable,
wherein the MCX cable is connected to the second PCB at a first end of the MCX cable.

7. The USB modem of claim 5, wherein the USB plug further comprises:
a connection terminal connected to a first end of the MCX cable,
wherein the MCX cable is connected to the second PCB at a second end of the MCX cable.

8. The USB modem of claim 6, wherein the MCX cable comprises:
a conductor;
an insulator surrounding the conductor;
an electromagnetic interference (EMI) shielding tape surrounding the insulator; and
a jacket tape surrounding the EMI shielding tape,
wherein a portion of the EMI shielding tape of the MCX cable is exposed to electrically connect the MCX cable to the conductive member.

9. The USB modem of claim 6, wherein the conductive member is electrically connected to the first PCB.

10. The USB modem of claim 7, wherein the connection terminal is electrically connected to the first PCB.

11. A method for forming a universal serial bus (USB) modem, comprising:
arranging an antenna in a first case;
arranging a first printed circuit board (PCB) in a second case;
connecting a second PCB to a USB terminal; and
connecting a first end of a micro-coaxial (MCX) cable to the second PCB,
wherein the antenna is grounded to the second PCB via the MCX cable.

12. The method of claim 11, further comprising:
connecting a connection terminal of the MCX cable to a connection port of the second case.

13. The method of claim 11, further comprising:
exposing an electromagnetic interference (EMI) shielding tape of the MCX cable to be connected to a conducting member; and
connecting the conducting member to a connection port of the second case.
